(19) United States
(12) Patent Application Publication
(10) Pub. No.: US 2016/0380110 A1
(43) Pub. Date: Dec. 29, 2016

(54) DISPLAY PANEL

(71) Applicant: InnoLux Corporation, Miao-Li County (TW)

(72) Inventors: Kuanfeng LEE, Miao-Li County (TW); Tzu-Min YAN, Miao-Li County (TW); Tsang-Lung CHEN, Miao-Li County (TW); YuCheng WANG, Miao-Li County (TW)

(21) Appl. No.: 15/168,389

(22) Filed: May 31, 2016

(30) Foreign Application Priority Data
Jun. 23, 2015 (TW) 104120138

(51) Int. Cl. H01L 29/786; H01L 29/423; H01L 27/12; H01L 29/45

(52) U.S. Cl. CPC H01L 29/78606; H01L 29/45; H01L 29/7869; H01L 29/42356; H01L 27/1225; H01L 27/3262

(57) ABSTRACT

A display panel is disclosed, which comprises: a substrate; a gate electrode disposed on the substrate; a gate insulation layer disposed on the substrate and the gate electrode; an active layer disposed on the gate insulation layer and over the gate electrode; a source electrode and a drain electrode disposed on the active layer; a first protection layer disposed on at least one of the source electrode and the drain electrode; and a metal oxide layer formed on a sidewall of the at least one of the source electrode and the drain electrode.

### CROSS REFERENCE TO RELATED APPLICATION

This application claims the benefits of the Taiwan Patent Application Serial Number 104120138, filed on Jun. 23, 2015, the subject matter of which is incorporated herein by reference.

### BACKGROUND OF THE INVENTION

1. Field of the Invention

The present invention relates to a display panel, more particularly, to a display panel comprising a thin film transistor substrate wherein peeling of layers from the source electrode and the drain electrode can be prevented.

2. Description of Related Art

As display technology advances, all devices are now being developed in smaller sizes with thinner thicknesses and lighter weights. Thus, the mainstream display devices in the market have changed from the previous cathode ray tube to the current thinner display devices. In particular, liquid crystal display panel and organic light emitting diode display panel have many applications in current display devices used in daily life such as in mobile phones, laptop computers, video cameras, cameras, music players, mobile navigation devices, and televisions.

In both liquid crystal display panel and organic light emitting diode display panel, at least one of the substrate is a thin film transistor substrate. Currently, there is a variety of thin film transistor substrate. The most common material for the active layer of thin film transistor substrate is amorphous silicon, metal oxide semiconductor, or low temperature polysilicon. Among them, the thin

film transistor made from IGZO, which is one of the metal oxide semiconductors, is the most popular, due to its extremely low leakage current.

### SUMMARY OF THE INVENTION

A display panel of the present disclosure comprises: a substrate; a gate electrode disposed on the substrate; a gate insulation layer disposed on the substrate and the gate electrode; an active layer disposed on the gate insulation layer and over the gate electrode; a source electrode and a drain electrode disposed on the active layer; a first protection layer disposed on at least one of the source electrode and the drain electrode; and a metal oxide layer formed on a sidewall of the at least one of the source electrode and the drain electrode.

In an embodiment of the display panel of the present disclosure, the source electrode and the drain electrode respectively comprise an undercut portion under the first protection layer. More specifically, a sidewall of the first protection layer is protruded compared to the sidewall of the at least one of the source electrode and the drain electrode.

In another embodiment of the display panel of the present disclosure, the sidewalls of the source electrode and the drain electrode comprise an inclined surface. A side of the inclined surface relatively farther away from the first protection layer is protruded compared to another side of the inclined surface.

In the display panel of the present disclosure, the source electrode and the drain electrode comprise a metal layer respectively. A material of the metal layer is copper, molybdenum, aluminum, titanium, or the combinations thereof. Or, the source electrode and the drain electrode comprise plural metal layers respectively. Materials of the plural metal layers comprise copper/molybdenum, copper/titanium, molybdenum/copper/molybdenum, molybdenum/aluminum/molybdenum, or molybdenum/aluminum/titanium.

In the display panel of the present disclosure, a material of the active layer is IGZO, ITZO, IGTO, IGZTO, ZnON, or the combinations thereof, but preferably IGZO.

The display panel of the present disclosure may selectively further comprises a second protection layer disposed between the active layer and the at least one of the source electrode and the drain electrode. The at least one of the source electrode and the drain electrode is interposed between the first protection layer and the second protection layer.

In the display panel of the present disclosure, the source electrode and the drain electrode may respectively comprise an undercut portion between the first protection layer and the second protection layer. More specifically, sidewalls of the first protection layer and the second protection layers are protruded compared to the sidewall of the at least one of the source electrode and the drain electrode.

A material of the first protection layer may be a transparent metal oxide or an insulation material. However, a material of the second protection layer can only be a transparent metal oxide. Examples of the transparent metal oxide comprise ITO, IZO, AZO, GZO, IGZO, ITZO, or the combinations thereof. Examples of the insulation material comprise silicon nitride, aluminum oxide, titanium oxide, or the combinations thereof.

In the display panel of the present disclosure, the source electrode and the drain electrode may comprise a metallic element respectively. When a thin film transistor substrate only comprises the first protection layer, the first protection layer may also comprise the same kind of the metallic element. When a thin film transistor substrate comprises both the first protection layer and the second protection layer, both the first protection layer and the second protection layer may also comprise the same kind of the metallic element respectively. A content of the metallic element in the first protection layer may be 1-8 at %, and preferably 4-5 at %. A content of the metallic element diffused to the second protection layer may be 3-10 at %, and preferably 5-5-6.5 at %.

In the display panel of the present disclosure, a content of oxygen atom in the metal oxide layers is 20-30 at %.

The display panel of the present disclosure, comprising: a substrate as described above; a counter substrate; and a display medium interposed between the substrate and the counter substrate.

In the display panel provided by the present disclosure, since a protection layer is further disposed on the source electrode and the drain electrode; hence, during the subsequent annealing of the active layer and N₂O processing, metal oxide layers will only form on sidewalls of the source electrode and the drain electrode. Metal oxide layers will not form on surfaces where the source electrode and other layers are in contact or on the surfaces where the drain electrode and other layers are in contact. Accordingly, peeling of layers from the source electrode and the drain electrode of a thin film transistor unit can be prevented. The properties of the thin film transistor unit made can be further improved. The display quality of a display panel provided by the present disclosure comprising a thin film transistor unit with improved properties can be further enhanced.

Other objects, advantages, and novel features of the present disclosure will become more apparent from the following detailed description when taken in conjunction with the accompanying drawings.

### BRIEF DESCRIPTION OF THE DRAWINGS

FIGS. 1A-1F are schematic diagrams showing a manufacturing process of a thin film transistor substrate of example 1 of the present disclosure in cross-sectional views.;

FIGS. 2A-2C are schematic diagrams showing a manufacturing process of an embodiment of a metal layer of example 1 of the present disclosure in cross-sectional views.;

FIGS. 3A-3C are schematic diagrams showing a manufacturing process of an embodiment of a metal layer of example 1 of the present disclosure in cross-sectional views.;

FIGS. 4A-4F are schematic diagrams showing a manufacturing process of a thin film transistor substrate of example 2 of the present disclosure in cross-sectional views.;

FIGS. 5A-5C are schematic diagrams showing a manufacturing process of an embodiment of a metal layer of example 2 of the present disclosure in cross-sectional views.;

FIGS. 6A-6C are schematic diagrams showing a manufacturing process of an embodiment of a metal layer of example 2 of the present disclosure in cross-sectional views.;

FIGS. 7A-7C are schematic diagrams showing a manufacturing process of an embodiment of a metal layer of example 2 of the present disclosure in cross-sectional views.;

FIGS. 8 and 9 show the results of elemental analyses of the partial region of the thin film transistor substrate shown in FIG. 4F at the A-A′ and B-B′ cross-sectional lines, respectively.;

FIGS. 10A-10C are schematic diagrams showing a manufacturing process of an embodiment of a metal layer of example 3 of the present disclosure in cross-sectional views.;

FIGS. 11A-11C are schematic diagrams showing a manufacturing process of an embodiment of a metal layer of example 3 of the present disclosure in cross-sectional views.;

FIG. 12 is a schematic diagram showing a cross-sectional view of a display panel of example 4 of the present disclosure.; and

FIG. 13 is a schematic diagram showing a cross-sectional view of a touch display device of example 5 of the present disclosure.

### DETAILED DESCRIPTION OF THE PREFERRED EMBODIMENT

### EXAMPLE 1

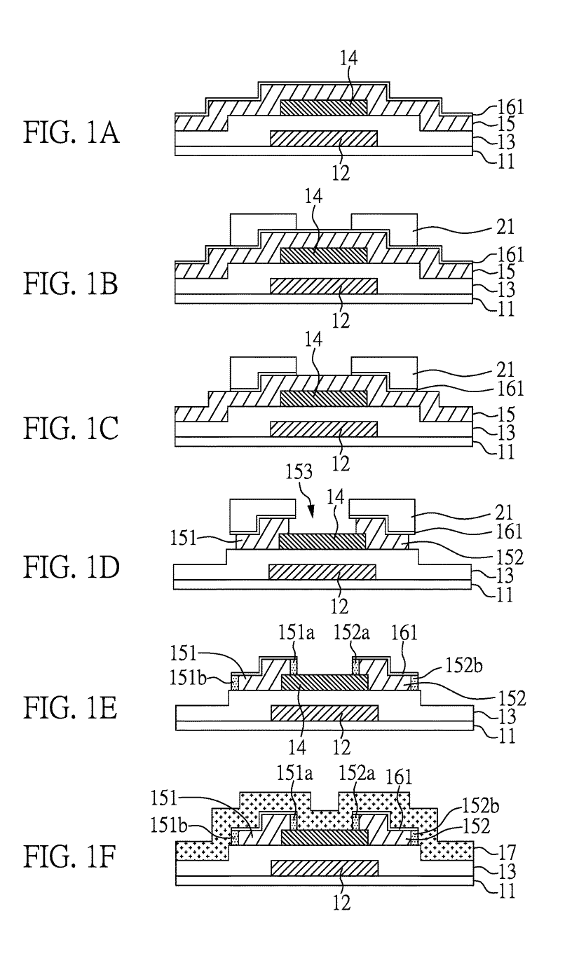

Please refer to FIGS. 1A-1F. FIGS. 1A-1F are schematic diagrams showing a manufacturing process of a thin film transistor substrate of the present example in cross-sectional views. First, as shown in FIG. 1A, a substrate 11 is provided with a gate electrode 12, a gate insulation layer 13, an active layer 14, and a metal layer 15 disposed thereon sequentially. The gate electrode 12, the gate insulation layer 13, the active layer 14, and the metal layer 15 can be formed by any methods known in the art. The substrate 11 can be made by any substrate materials known in the art such as glass, plastic, and other flexible materials. The gate insulation layer 13 can be made by any insulation layer materials known in the art such as oxides, nitrides, or nitrogen oxides. The active layer 14 can be made by any metal oxide semiconductor materials known in the art such as IGZO, ITZO, IGTO, IGZTO, ZnON, and combinations thereof. In particular, the material of the active layer 14 in the present example is IGZO. The gate electrode 12 and the metal layer 15 can be made by any conductive materials known in the art such as metal, alloy, or electrode materials known in other arts, but preferably metal materials.

After the metal layer 15 is formed, a first protection layer 161 is formed thereon. The thickness of the first protection layer 161 is 100-3000 Å and preferably 100-500 Å. As shown in FIG. 1B, a photoresist 21 is formed on the first protection layer 161. As shown in FIG. 1C, the first protection layer 161 is then patterned by etching to have a pattern same as the pattern of the photoresist 21. The method used to pattern the first protection layer 161 depends on the material of the first protection layer 161. In the present example, a material of the first protection layer 161 may be a transparent metal oxide or an insulation material. Examples of the transparent metal oxides comprise ITO, IZO, AZO, GZO, IGZO, ITZO, and combinations thereof. Examples of the insulation material comprise silicon nitride (SiNx), aluminum oxide (AlOx), titanium oxide (TiOx), and combinations thereof, but preferably silicon nitride. When the first protection layer 161 is made by a transparent metal oxide, wet etching can be used for its patterning. The etching solution used can be any etching solutions known in the art such as oxalic acid or a mixture of phosphoric acid, acetic acid, and nitric acid (phosphoric-acetic-nitric; PAN). When the first protection layer 161 is made by an insulation material, either dry etching or wet etching can be used for its patterning. In particular, the dry etching can be performed using a gas comprising SF₆/O₂ or CF₄ and the wet etching can be performed using a silicon dioxide etching agent comprising HF (buffered oxide etch; BOE).

As shown in FIG. 1D, after the first protection layer 161 is patterned, the metal layer 15 is also patterned to define a source electrode 151 and a drain electrode 152 as well as a channel 153 between the source electrode 151 and the drain electrode 152 to reveal the active layer 14. The method used to pattern the metal layer 15 depends on the material of the metal layer 15 and either wet etching and dry etching can be used. Details regarding the materials of the metal layer 15 and the corresponding etching methods that can be used for its patterning will be described later.

When the metal layer 15 is being patterned, oxygen deficiency will increase easily on the surface of the active layer 14, causing the thin film transistor unit made to have poor properties. As a result, a recovery step comprising annealing and N₂O(g) treatment is performed after the metal layer 15 is patterned in order to recover the semiconductor properties of the active layer 14. As shown in FIG. 1F, when the recovery step is performed, metal oxide layers 151a, 151b, 152a, and 152b are formed respectively on sidewalls of the source electrode 151 and the drain electrode 152. Finally, as shown in FIG. 1F, an insulation layer 17 is formed to complete a manufacturing process of a thin film transistor substrate of the present example.

As shown in FIG. 1F, a thin film transistor substrate of the present example comprises: a substrate 11; a gate electrode 12 disposed the substrate 1; a gate insulation layer 13 disposed on the substrate 11 and the gate electrode 12; an active layer 14 disposed on the gate insulation layer 13 and over the gate electrode 12; a source electrode 151 and a drain electrode 152 disposed on the active layer 14 and a channel 153 is disposed between the source electrode 151 and the drain electrode 152 to reveal the active layer 14; a first protection layer 161 disposed on the source electrode 151 and the drain electrode 152; and metal oxide layers 151a, 151b, 152a, 152b formed on sidewalls of the source electrode 151 and the drain electrode 152. In particular, the metal oxide layers 151a, 151b, 152a, and 152b are formed on all sidewalls of the source electrode 151 and the drain electrode 152 as well as on all sidewalls adjacent to the channel 153.

Next, different embodiments of the formations of the metal oxide layers 151a, 151b on the sidewalls of the source electrode 151 shown in FIG. 1E will be described in detail. Since the material of the drain electrode 152 is the same as that of the source electrode 151, descriptions regarding the drain electrode 152 will not be repeated.

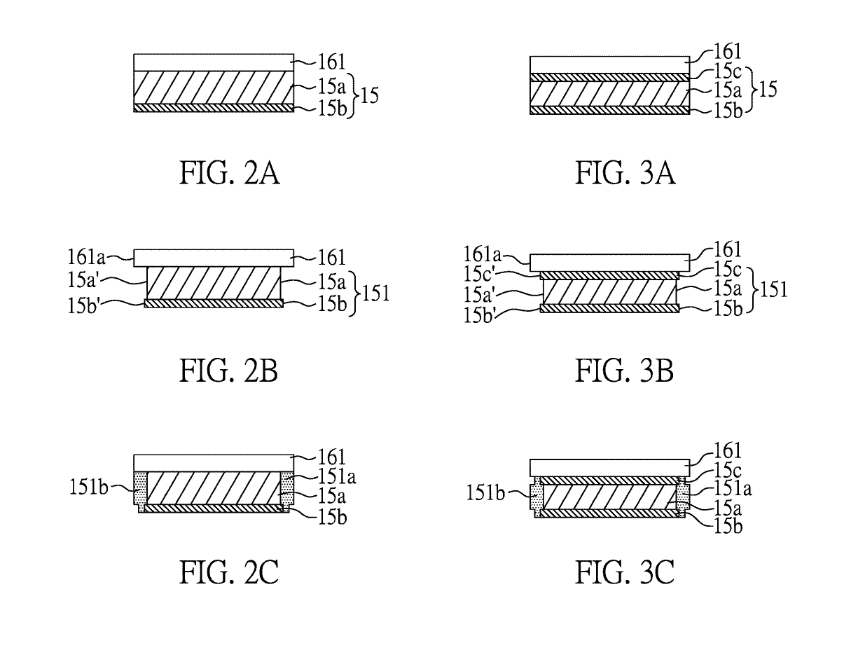

Please refer to FIGS. 2A-2C. FIGS. 2A-2C are schematic diagrams showing a manufacturing process of an embodiment of a metal layer of the present example in cross-sectional views. First, as shown in FIGS. 1C and 2A, the metal layer 15 may be a double layer metal structure comprising a first metal layer 15a and a second metal layer 15b. The material of the first metal layer 15a is copper. The material of the second metal layer 15b is molybdenum or titanium. After etching, as shown in FIGS. 1D and 2B, the source electrode 151 comprises an undercut portion under the first protection layer 161. More specifically, a sidewall 161a of the first protection layer 161 is protruded compared to a sidewall 15a′ of the first metal layer 15a and a sidewall 15b′ of the second metal layer 15b of the source electrode 151. Since the etching rate of the first metal layer 15a is faster compared to that of the second metal layer 15b, consequently, the sidewall 15b′ of the second metal layer 15b is protruded compared to the sidewall 15a′ of the first metal layer 15a. After the recovery step, as shown in FIGS. 1E and 2C, the metal oxide layers 151a, 151b are formed on the sidewalls 15a′, 15b′ of the first metal layer 15a and the second metal layer 15b. Since the oxidation rate of copper is faster than that of molybdenum or titanium; thus, the copper oxide formed on the sidewall 15a′ of the first metal layer 15a is thicker than the molybdenum oxide or titanium oxide formed on the sidewall 15b′ of the second metal layer 15b.

When the first metal layer 15a is a copper layer and the second metal layer 15b is a molybdenum layer, wet etching can be used to pattern the first metal layer 15a and the second metal layer 15b using a H₂O₂ etching solution. When the first metal layer 15a is a copper layer and the second metal layer 15b is a titanium layer, the first metal layer 15a is patterned using a H₂O₂ etching solution and the second metal layer 15b is patterned by dry etching.

Please refer to FIGS. 3A-3C. FIGS. 3A-3C are schematic diagrams showing a manufacturing process of another embodiment of a metal layer of the present example in cross-sectional views. The embodiment shown in FIGS. 3A-3C is similar to the embodiment shown in FIGS. 2A-2C, except the metal layer 15 shown in FIGS. 3A-3C further comprises a third metal layer 15c. The material of the third metal layer 15c is molybdenum. After etching, as shown in FIGS. 1D and 3B, a sidewall 161a of the first protection layer 161 is protruded compared to a sidewall 15c′ of the third metal layer 15c. The sidewall 15c′ is also protruded compared to a sidewall 15a′ of the first metal layer 15a. After the recovery step, as shown in FIGS. 1E and 3C, the metal oxide layers 151a, 151b are formed on the sidewalls 15c′ of the third metal layer 15c. The metal oxide layers 151a, 151b formed on the sidewalls 15a′ of the first metal layer 15a are thicker than the metal oxide layers 151a, 151b formed on the sidewalls 15c′ of the third metal layer 15c.

When the first metal layer 15a is a copper layer and both the second metal layer 15b and the third metal layer 15c are molybdenum layers, wet etching can be used to pattern the first metal layer 15a, the second metal layer 15b, and the third metal layer 15c using a H₂O₂ etching solution.

### EXAMPLE 2

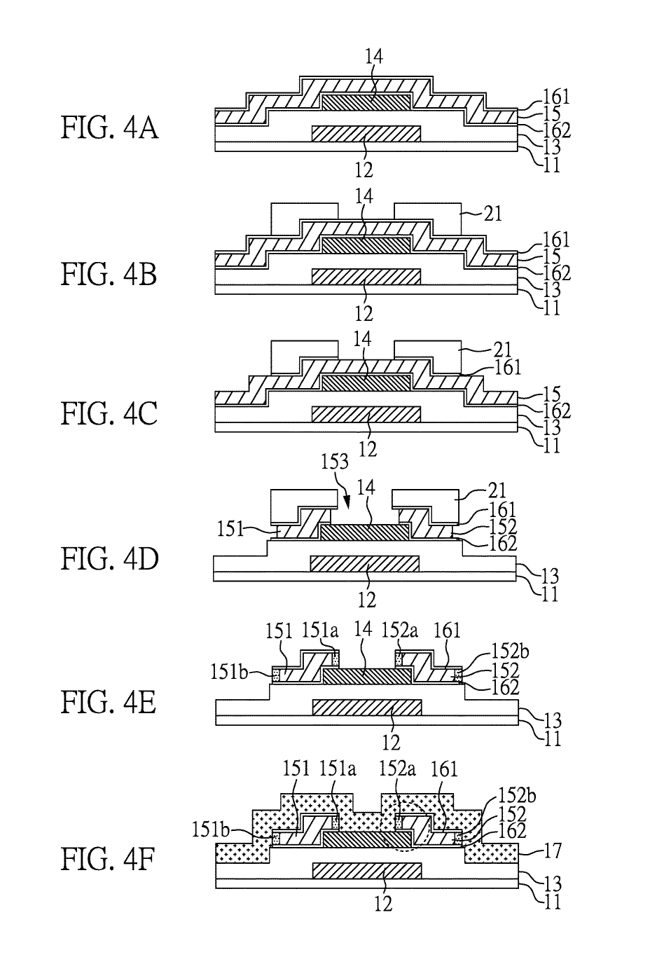

Please refer to FIGS. 4A-4F. FIGS. 4A-4F are schematic diagrams showing a manufacturing process of a thin film transistor substrate of the present example in cross-sectional views. The manufacturing process, structure, material of the thin film transistor substrate of the present example is similar to that of Example 1, except of the following.

As shown in FIG. 4A, in the thin film transistor substrate of the present example, a second protection layer 162 is formed after the active layer 14 is formed. The thickness of the second protection layer 162 is 100-3000 Å and preferably 100-500 Å. A material of the second protection layer 162 may be a transparent metal oxide. Examples of the transparent metal oxides comprise ITO, IZO, AZO, GZO, IGZO, ITZO, and combinations thereof. In addition, as shown in FIG. 4D, not only the metal layer 15 is being patterned to define the source electrode 151 and the drain electrode 152, but the second protection layer 162 is also being patterned in order to reveal the active layer 14 at the channel 153. Since a material of the second protection layer 162 may be a transparent metal oxide, hence, it also comprises a conductive property. Therefore, the source electrode 151 and the active layer 14 as well as the drain electrode 152 and the active layer 14 may be electrically connected.

Comparing to the thin film transistor substrate of example 1 shown in FIG. 1F, the thin film transistor substrate of the present example shown in FIG. 4F, further comprises: a second protection layer 162 disposed between the active layer 14 and the source electrode 151 as well as between the active layer 14 and the drain electrode 152, and the source electrode 151 and the drain electrode 152 are interposed between the first protection layer 161 and the second protection layer 162.

Next, different embodiments of the formations of the metal oxide layers 151a, 151b on the sidewalls of the source electrode 151 shown in FIG. 4E will be described in detail. Since the material of the drain electrode 152 is the same as that of the source electrode 151, descriptions regarding the drain electrode 152 will not be repeated.

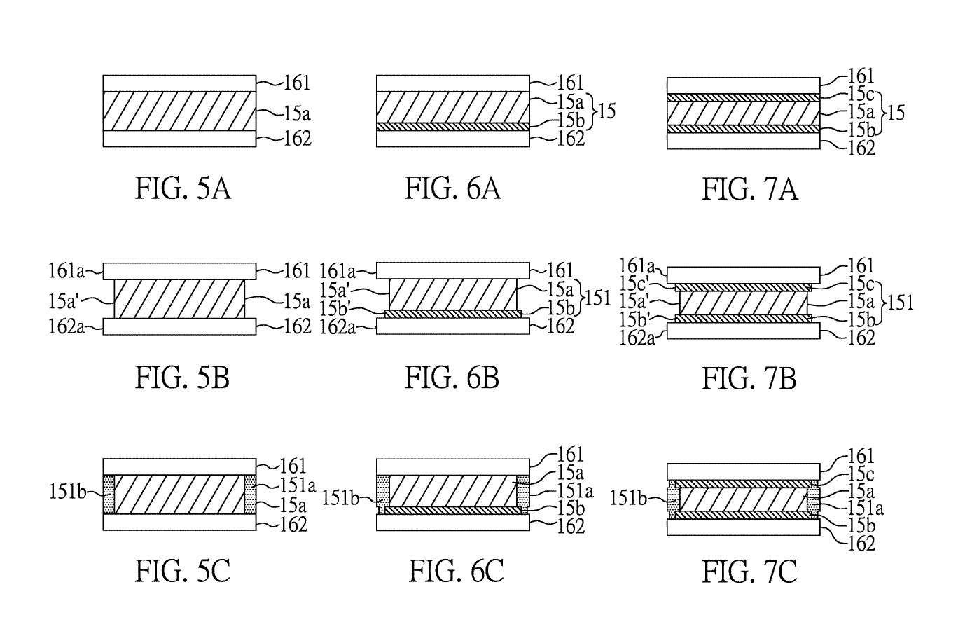

Please refer to FIGS. 5A-5C. FIGS. 5A-5C are schematic diagrams showing a manufacturing process of an embodiment of a metal layer of the present example in cross-sectional views. First, as shown in FIGS. 4C and 5A, the metal layer 15 may be a single layer metal structure comprising a first metal layer 15a. The material of the first metal layer 15a is copper. After etching, as shown in FIGS. 4D and 5B, the source electrode 151 comprises an undercut portion under the first protection layer 161. More specifically, a sidewall 161a of the first protection layer 161 is protruded compared to a sidewall 15a′ of the first metal layer 15a of the source electrode 151. A sidewall 162a of the second protection layer 162 is also protruded compared to a sidewall 15a′ of the first metal layer 15a of the source electrode 151. After the recovery step, as shown in FIGS. 4E and 5C, the metal oxide layers 151a, 151b are formed on the sidewalls 15a′ of the first metal layer 15a.

Please refer to FIGS. 6A-6C. FIGS. 6A-6C are schematic diagrams showing a manufacturing process of another embodiment of a metal layer of the present example in cross-sectional views. The embodiment shown in FIGS. 6A-6C is similar to the embodiment shown in FIGS. 2A-2C, except a second protection layer 162 is formed under the metal layer 15 as shown in FIGS. 6A-6C. A sidewall 161a of the first protection layer 161 and a sidewall 162a of the second protection layer 162 are protruded compared to a sidewall 15a′ of the first metal layer 15a and a sidewall 15b′ of the second metal layer 15b.

Please refer to FIGS. 7A-7C. FIGS. 7A-7C are schematic diagrams showing a manufacturing process of another embodiment of a metal layer of the present example in cross-sectional views. The embodiment shown in FIGS. 7A-7C is similar to the embodiment shown in FIGS. 3A-3C, except a second protection layer 162 is formed under the metal layer 15 as shown in FIGS. 7A-7C. A sidewall 161a of the first protection layer 161 and a sidewall 162a of the second protection layer 162 are protruded compared to a sidewall 15a′ of the first metal layer 15a, a sidewall 15b′ of the second metal layer 15b, and a sidewall 15c′ of the third metal layer 15c.

### EXPERIMENT EXAMPLE

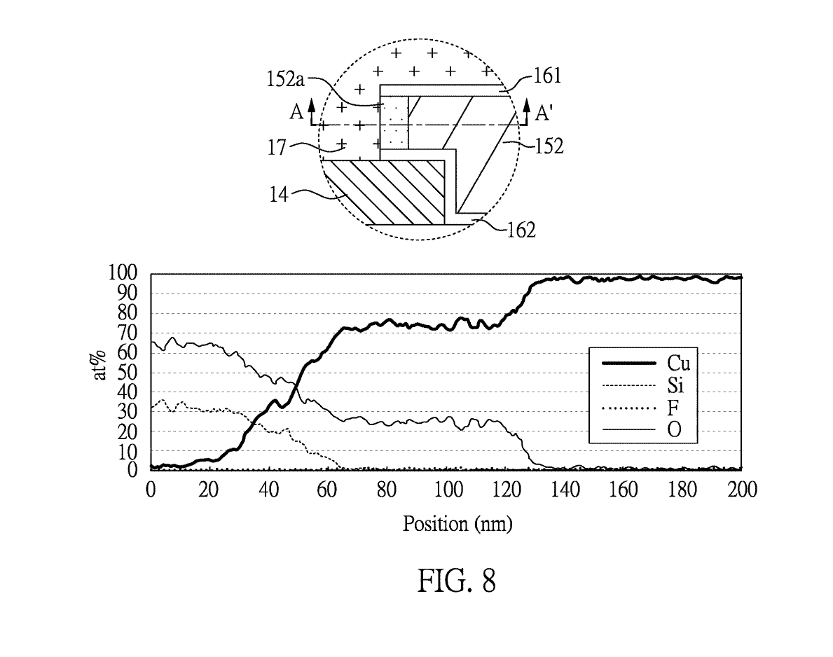

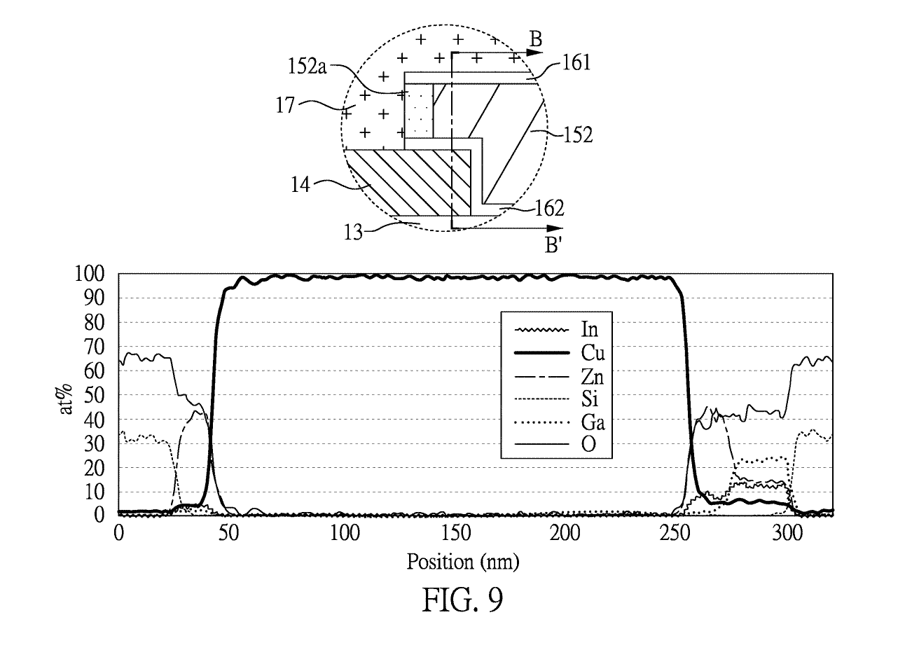

Please refer to FIGS. 4F, 5C, 8, and 9. FIGS. 8 and 9 show the results of elemental analyses of the partial region (circled region) of the thin film transistor substrate shown in FIG. 4F and when the metal layer 15a is a copper layer shown in FIG. 5C. Specifically, the regions shown in the circles in FIGS. 8 and 9 correspond to the enlarged circled region in FIG. 4F.

As shown in FIG. 8, when an elemental analysis is conducted along the A-A′ cross-sectional line, the main elemental composition of the region between the relative positions of 0 nm and 60 nm is Si and O, which corresponds to the insulation layer 17 made by SiOx. The main elemental composition of the region between the relative positions of 60 nm and 120 nm is Cu and O, which corresponds to the metal oxide layer 152 made by CuOx. The main elemental composition of the region between the relative positions of 120 nm and 200 nm is Cu, which corresponds to the drain electrode 152 made by Cu. As known from the results, after the recovery step, the thickness of the metal oxide layer 152a formed on the sidewall of the drain electrode 152 is about 60 nm. The content of oxygen atom in the metal oxide layer 152a is 20-30 at %. However, the thickness and the content of oxygen atom of the metal oxide layer 152a are not limited thereto and can be changed according to different conditions used in the recovery step.

As shown in FIG. 9, when an elemental analysis is conducted along the B-B′ cross-sectional line, the main elemental composition of the region between the relative positions of 0 nm and 25 nm is Si and O, which corresponds to the insulation layer 17 made by SiOx. The main elemental composition of the region between the relative positions of 25 nm and 50 nm is Zn and O with a small amount of In, which corresponds to the first protection layer 161 made by IZO. The main elemental composition of the region between the relative positions of 50 nm and 250 nm is Cu, which corresponds to the drain electrode 152 made by Cu. The main elemental composition of the region between the relative positions of 250 nm and 270 nm is Zn and O with a small amount of In, which corresponds to the second protection layer 162 made by IZO. The main elemental composition of the region between the relative positons of 270 nm and 300 nm are In, Ga, Zn, and O, which corresponds to the active layer 14 made by IGZO. The main elemental composition of the region at the relative positions after 300 nm are Si and O, which corresponds to the gate insulation layer 13 made by SiOx.

It should be noted from FIG. 9 that the elemental compositions of the regions between the relative positions of 25 nm and 50 nm as well as between the relative positions of 250 nm and 300 nm further comprise small amounts of Cu. These results indicate that during the recovery step, the metallic elements in the source electrode (not shown) and the drain electrode 152 partly diffuse to the first protection layer 161 and the second protection layer 162. These diffusions cause the first protection layer 161 and the second protection layer 162 to comprise the metallic elements of the source electrode (not shown) and the drain electrode 152. In the present example, the copper of the drain electrode 152 partly diffuses to the first protection layer 161 to cause the first protection layer 161 to have a copper atom content of 4.0-5.0 at %. The second protection layer 162 has a copper atom content of 5.5-6.5 at %. The contents of the metallic element in the drain electrode 152 diffused to the first protection layer 161 and the second protection layer 162 can be changed according to different conditions used in the recovery step. However, it is preferred that the content of the metallic atom diffused to the second protection layer 162 is greater than that diffused to the first protection layer 161. It is more preferable that the content of the metallic atom diffused to the first protection layer 161 is 1-8 at % and that diffused to the second protection layer is 3-10 at %.

### EXAMPLE 3

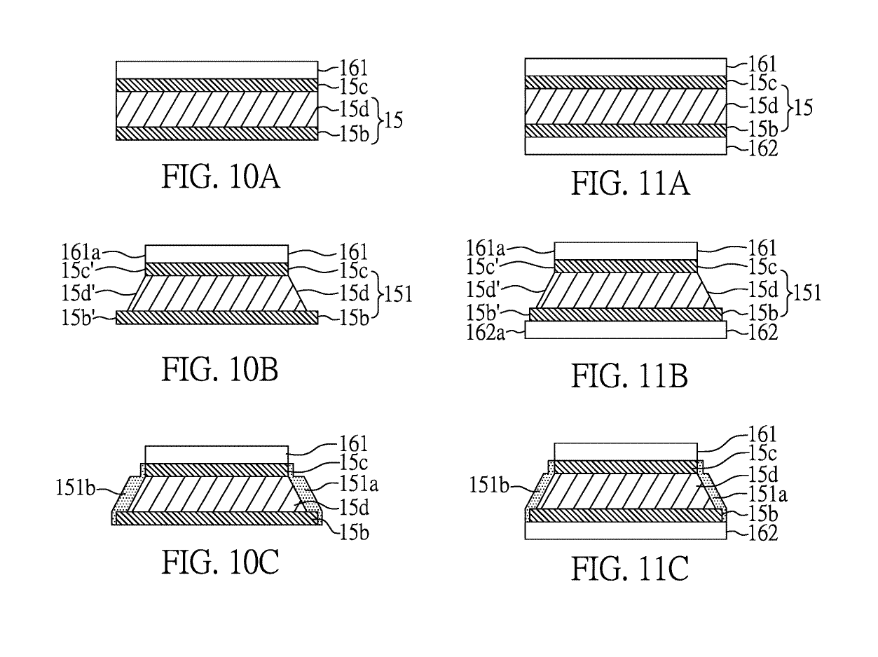

Please refer to FIGS. 10A-10C and 11A-11C. The manufacturing process, structure, material of the thin film transistor substrate of the present example is similar to that of Examples 1 and 2, except of the following.

FIGS. 10A-10C are schematic diagrams showing a manufacturing process of an embodiment of a metal layer of the present example in cross-sectional views. The embodiment shown in FIGS. 10A-10C is similar to the embodiment shown in FIGS. 3A-3C, except a fourth metal layer 15, which is an aluminum layer, replaces the first metal layer 15a, which is a copper layer, as shown in FIGS. 10A-10C. Since the fourth metal layer 15 is an aluminum layer; therefore, the fourth metal layer 15 can be patterned by etching using a mixture of phosphoric acid, acetic acid, and nitric acid (phosphoric-acetic-nitric; PAN) as the etching solution. After the recovery step, the metal oxide layers 151a, 151b (aluminum oxides) are also formed on the sidewalls 15d′ of the fourth metal layer 15d.

As shown in FIGS. 10B and 10C, since the etching of aluminum is different from that of copper; thus, when the fourth metal layer 15d is patterned by wet etching, each sidewall 15d′ of the fourth metal layer 15d of the source electrode 151 comprises an inclined surface. The sidewall of the inclined surface relatively farther away from the first protection layer 161 is protruded compared to another sidewall of the inclined surface.

FIGS. 11A-11C are schematic diagrams showing a manufacturing process of another embodiment of a metal layer of the present example in cross-sectional views. The embodiment shown in FIGS. 11A-11C is similar to the embodiment shown in FIGS. 10A-10C, except a second protection layer 162 is formed under the second metal layer 15b as shown in FIGS. 11A-11C.

### EXAMPLE 4

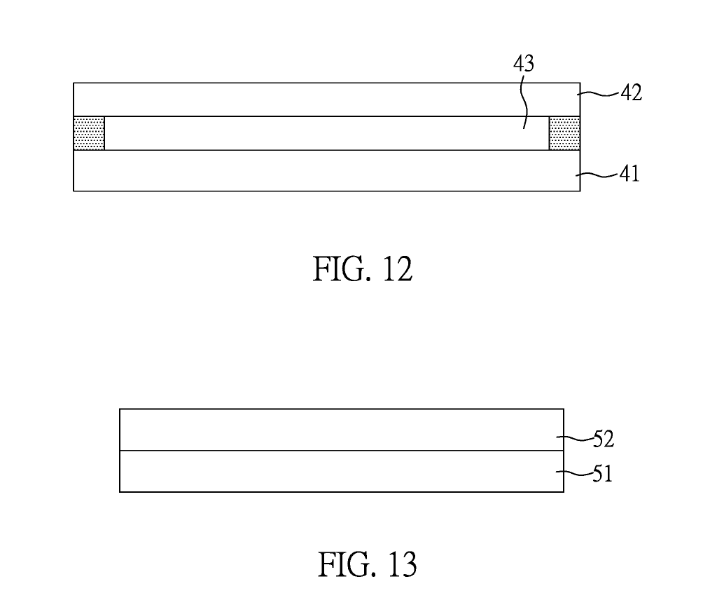

In the present example, a thin film transistor substrate as described above is applied in a display panel. As shown in FIG. 12, a display panel of the present example comprises: a thin film transistor substrate 41; a counter substrate 42; and a display medium 43 interposed between the thin film transistor substrate 41 and the counter substrate 42. In the present example, the display medium 43 can be a liquid crystal layer or an organic light emitting diode layer. The counter substrate 42 may be a color filter substrate with a color filter layer disposed thereon or a protection glass. However, in other examples, the color filter layer may be disposed on the thin film transistor substrate 41. In these cases, the thin film transistor substrate 41 may be an integrated color filter on array (COA) thin film transistor substrate.

The display panel provided by the present example can be used with a touch panel known in the art. As shown in FIG. 13, the touch display panel of the present example comprises: a display panel 51 as described above; and a touch panel 52 disposed on the display panel 51.

The display panel and the touch display panel made by the examples described above can be applied to any electronic devices requiring display screens known in the art, such as monitors, mobile phones, laptop computers, video cameras, cameras, music players, mobile navigation devices, and televisions.

Although the present invention has been explained in relation to its preferred embodiment, it is to be understood that many other possible modifications and variations can be made without departing from the spirit and scope of the invention as hereinafter claimed.

What is claimed is:

1. A display panel, comprising:
a substrate;
a gate electrode disposed on the substrate;
a gate insulation layer disposed on the substrate and the gate electrode;
an active layer disposed on the gate insulation layer and over the gate electrode;
a source electrode and a drain electrode disposed on the active layer;
a first protection layer disposed on at least one of the source electrode and the drain electrode; and
a metal oxide layer formed on a sidewall of the at least one of the source electrode and the drain electrode.

2. The display panel as claimed in claim 1, wherein a content of oxygen atom in the metal oxide layer is 20-30 at %.

3. The display panel as claimed in claim 1, wherein a material of the first protection layer is a transparent metal oxide.

4. The display panel as claimed in claim 3, wherein the transparent metal oxide is ITO, IZO, AZO, GZO, IGZO, ITZO, or the combinations thereof.

5. The display panel as claimed in claim 1, wherein a material of the first protection layer is an insulation material.

6. The display panel as claimed in claim 5, wherein the insulation material is silicon nitride, aluminum oxide, titanium oxide, or the combinations thereof.

7. The display panel as claimed in claim 1, wherein a sidewall of the first protection layer is protruded compared to the sidewall of the at least one of the source electrode and the drain electrode.

8. The display panel as claimed in claim 1, wherein the source electrode and the drain electrode comprise a metal layer respectively, and a material of the metal layer is copper, molybdenum, aluminum, titanium, or the combinations thereof.

9. The display panel as claimed in claim 8, wherein the source electrode and the drain electrode comprise plural metal layers respectively, and materials of the plural metal layers comprise copper/molybdenum, copper/titanium, molybdenum/copper/molybdenum, molybdenum/aluminum/molybdenum, or molybdenum/aluminum/titanium.

10. The display panel as claimed in claim 1, wherein the source electrode, the drain electrode, and the metal oxide layer comprise a metallic element respectively.

11. The display panel as claimed in claim 1, wherein the source electrode, the drain electrode, and the first protection layer comprise a metallic element respectively, and a content of the metallic element in the first protection layer is 1-8 at %.

12. The display panel as claimed in claim 1, further comprising a second protection layer disposed between the active layer and the at least one of the source electrode and the drain electrode, and the at least one of the source electrode and the drain electrode is interposed between the first protection layer and the second protection layer.

13. The display panel as claimed in claim 12, wherein a material of the second protection layer is a transparent metal oxide.

14. The display panel as claimed in claim 13, wherein the transparent metal oxide is ITO, IZO, AZO, GZO, IGZO, ITZO, or the combinations thereof.

15. The display panel as claimed in claim 12, wherein a sidewall of the second protection layer is protruded compared to the sidewall of the at least one of the source electrode and the drain electrode.

16. The display panel as claimed in claim 12, wherein the source electrode and the drain electrode comprise a metal layer respectively, and a material of the metal layer is copper, molybdenum, aluminum, titanium, or the combinations thereof.

17. The display panel as claimed in claim 16, wherein the source electrode and the drain electrode comprise plural metal layers respectively and materials of the plural metal layers comprise copper/molybdenum, copper/titanium, molybdenum/copper/molybdenum, molybdenum/aluminum/molybdenum, or molybdenum/aluminum/titanium.

18. The display panel as claimed in claim 12, wherein the first protection layer, the second protection layer, the source electrode, and the drain electrode comprise a metallic element respectively.

19. The display panel as claimed in claim 18, wherein a content of the metallic element in the first protection layer is 1-8 at %.

20. The display panel as claimed in claim 18, wherein a content of the metallic element in the second protection layer is 3-10 at %.

21. The display panel as claimed in claim 18, wherein a content of the metallic element in the second protection layer is greater than a content of the metallic element in the first protection layer.

22. The display panel as claimed in claim 1, further comprising:
a counter substrate; and
a display medium interposed between the substrate and the counter substrate.
